(19) United States
(12) Patent Application Publication
(10) Pub. No.: US 2026/0138868 A1
(43) Pub. Date: May 21, 2026

(54) MICRO-PARTICLE CLEANING METHOD FOR MICRO-ELECTROMECHANICAL SYSTEMS DEVICES WITH MOVABLE SURFACE STRUCTURES

(71) Applicant: Lumentum Operations LLC, San Jose, CA (US)

(72) Inventors: Edward WANG, Ottawa (CA); Wenlin JIN, Ottawa (CA); Michael MILLER, Ottawa (CA); Dean FLOCKTON, Kanata (CA); Chi-li-ma HARNOLD, Sugar Land, TX (US); Parsoua ABEDINI SOHI, Nepean (CA)

(21) Appl. No.: 19/049,656

(22) Filed: Feb. 10, 2025

Related U.S. Application Data
(60) Provisional application No. 63/722,361, filed on Nov. 19, 2024.

(51) Int. Cl. B81C 1/00; B08B 5/02; B08B 5/04; B08B 7/00; B08B 13/00

(52) U.S. Cl. CPC B81C 1/00849; B08B 5/02; B08B 5/04; B08B 7/0092; B08B 13/00

(57) ABSTRACT

A nozzle of a surface cleaning system includes one or more gas channels configured to direct a gas toward a target surface at a low angle relative to the target surface in order to dislodge particles from the target surface; and a vacuum channel configured to apply a vacuum to the target surface for vacuuming the particles away from the target surface.

### CROSS-REFERENCE TO RELATED APPLICATION

This Patent Application claims priority to U.S. Provisional Patent Application No. 63/722,361, filed on Nov. 19, 2024, and entitled “MICRO-PARTICLE CLEANING METHOD FOR MICRO-ELECTROMECHANICAL SYSTEMS DEVICES WITH MOVABLE SURFACE STRUCTURES.” The disclosure of the prior Application is considered part of and is incorporated by reference into this Patent Application.

### TECHNICAL FIELD

The present disclosure relates generally to micro-particle cleaning for micro-electromechanical systems (MEMS).

### BACKGROUND

A MEMS device is a micro-sized structure that has electronic and mechanical components and physical dimensions that may range from several millimeters to less than one micrometer. For example, a MEMS device may include a mirror that can be used to reflect or otherwise direct light (e.g., a laser beam) in various applications, such as a light detection and ranging (LIDAR) application, a sensing application, and/or an optical communications application, among other examples. In operation, a MEMS driver circuit may actuate the MEMS device, which may cause the mirror to be tilted about one or more axes in order to change a direction in which the light is directed by the mirror. For example, actuating the MEMS device to tilt the mirror may cause an optical beam that was falling upon the mirror and reflecting in one direction to be reflected in a different direction. Many other types of MEMS devices exist. MEMS devices may be manufactured on a wafer (e.g., a MEMS wafer), which may eventually be singulated into MEMS dies.

### SUMMARY

In some implementations, a surface cleaning system includes one or more gas sources configured to provide a gas at one or more respective gas pressures; a vacuum source configured to provide a vacuum at a vacuum pressure; a nozzle comprising: one or more gas channels fluidly coupled to the one or more gas sources, the one or more gas channels configured to direct the gas toward a target surface at a low angle relative to the target surface in order to dislodge particles from the target surface; and a vacuum channel fluidly coupled to the vacuum source, the vacuum channel configured to apply the vacuum to the target surface for vacuuming the particles away from the target surface; a movement mechanism attached to the nozzle or to an object of the target surface, wherein the movement mechanism is configured to change a position of the nozzle relative to the target surface according to a two-dimensional pattern; and a control system configured to control the one or more respective gas pressures of the gas in each gas channel of the one or more gas channels, the vacuum pressure of the vacuum within the vacuum channel, and a movement of the nozzle or the object via the movement mechanism.

In some implementations, a nozzle of a surface cleaning system includes one or more gas channels configured to direct a gas toward a target surface at a low angle relative to the target surface in order to dislodge particles from the target surface; and a vacuum channel configured to apply a vacuum to the target surface for vacuuming the particles away from the target surface.

In some implementations, a method for cleaning a surface includes injecting a gas into one or more gas channels of a nozzle; directing, at an exit of the nozzle, the gas toward a target surface at a low angle relative to the target surface in order to dislodge particles from the target surface; and applying, by a vacuum channel of the nozzle, a vacuum to the target surface for vacuuming the particles away from the target surface.

### BRIEF DESCRIPTION OF THE DRAWINGS

FIG. 1 shows a surface cleaning system according to one or more implementations.

FIGS. 2A and 2B show a portion of a surface cleaning system according to one or more implementations.

FIG. 3 shows an example of a scanning pattern of a nozzle relative to a target surface.

FIG. 4 is a flowchart of an example process associated with a micro-particle cleaning method for MEMS devices with movable surface structures.

### DETAILED DESCRIPTION

The following detailed description of example implementations refers to the accompanying drawings. The same reference numbers in different drawings may identify the same or similar elements.

A manufacturing yield for MEMS devices (e.g., a percentage or ratio of non-defective MEMS devices on a wafer) is very sensitive to particles and/or contaminants. For example, conductive particles and/or contaminants can cause electrical leakages or shortages that may result in a MEMS device being non-functional or defective. The particles and/or contaminants can also hinder mechanical movements for certain MEMS structures, which may also cause MEMS device failure, and/or may degrade performance for MEMS devices that are used in optical technologies, such as LIDAR.

However, cleaning particles and/or contaminants from a MEMS device poses various challenges, especially for MEMS devices that may have movable surface structures (e.g., a large number of optical mirror arrays). For example, in a cleaning system that sprays a high-speed cleaning mixture onto a wafer surface, the movable surface structures of a MEMS device can be damaged by the high-speed spray. Furthermore, particles and/or contaminants that are blown off the surface by the high-speed spray may then land again on other places on the MEMS device and/or become trapped in gaps or cavities, causing irreversible damage or faults.

Accordingly, some implementations described herein relate to a method and/or system for cleaning micro-particles from a target surface, such as a wafer surface of a wafer. The wafer may be a MEMS wafer that includes MEMS devices. Thus, the wafer surface may include MEMS structures (e.g., movable surface structures) of the MEMS devices. For example, the MEMS wafer may include MEMS mirror structures arranged at the target surface. Additionally, the wafer surface may include one or more openings that lead into one or more internal cavities of the MEMS devices, where internal MEMS structures reside. The cleaning method and/or system may remove the micro-particles from the target surface without damaging the MEMS structures. Additionally, the cleaning method and/or system may remove the micro-particles in such a way that the micro-particles are not re-deposited onto the target surface or within the one or more internal cavities.

For example, in some implementations, the cleaning method and/or system may use a high-speed and low-angle gas flow directed at the target surface to dislodge particles with a minimum downward pressure at the surface of MEMS device, while providing a lifting force for dislodging the particles from the target surface. In this way, the high-speed and low-angle gas flow may remove particles from the target surface of a MEMS wafer without damaging the MEMS structures of the MEMS devices. Furthermore, the cleaning method and/or system may use a rapid temperature drop on particles due to an adiabatic cooling to weaken an adhesion between particles and the target surface, and/or may apply a vacuum and/or Venturi forces to pick up and remove particles from the target surface to prevent particles from relocating to other areas of the MEMS wafer. After cleaning, the wafer may be singulated into separate devices or dies.

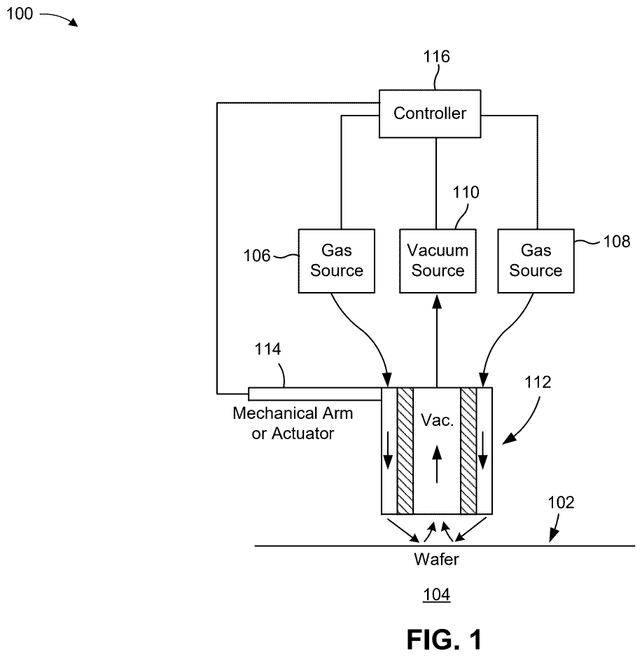

FIG. 1 shows a surface cleaning system 100 according to one or more implementations. The surface cleaning system 100 may be associated with cleaning micro-particles from a target surface 102 of an object 104. For example, the object may be a wafer, such as a MEMS wafer. Thus, the target surface may be a wafer surface. The MEMS wafer may have plurality of MEMS structures (e.g., movable surface structures) arranged at the target surface. For example, the MEMS wafer may include MEMS mirror devices, and the MEMS wafer may include a plurality of MEMS mirror structures arranged at the target surface.

The surface cleaning system 100 may include one or more gas sources 106 and 108, a vacuum source 110, a nozzle 112, a movement mechanism 114, and a control system 116 (e.g., a controller). The one or more gas sources 106 and 108 may provide a gas, such as carbon dioxide (CO₂) gas, at respective gas pressures. The vacuum source 110 may provide a vacuum at a vacuum pressure. For example, the vacuum source 110 may be a dry mechanical vacuum pump.

The nozzle 112 may include one or more gas channels fluidly coupled to the one or more gas sources 106 and 108. The one or more gas channels may direct the gas toward the target surface 102 at a low angle relative to the target surface 102 in order to dislodge particles (e.g., micro-particles) from the target surface 102.

In some implementations, the low angle may be in a range of 1-30°. In some implementations, the gas is configured to form a mixture of gas and gas ice crystals via adiabatic cooling to dislodge the particles from the target surface 102. In some implementations, the gas induces a temperature drop at the target surface 102 to weaken a bond between particles and the target surface 102, thereby facilitating the removal of the particles from the target surface 102.

In addition, the nozzle 112 may include a vacuum channel fluidly coupled to the vacuum source. The vacuum channel may apply the vacuum to the target surface 102 for vacuuming the particles away from the target surface 102. In some implementations, the vacuum channel is a center channel that extends along a center axis of the nozzle, and the one or more gas channels are arranged at a periphery of the nozzle 112, peripheral to the vacuum channel. In some implementations, a single gas channel may be provided. The single gas channel may surround the vacuum channel. For example, the single gas channel may have a cylindrical shape.

The movement mechanism 114 may be attached to the nozzle 112, as shown in FIG. 1. Alternatively, the movement mechanism 114 may be attached to the object 104 (e.g., to the wafer) or to an object that holds or otherwise is coupled to the object 104. For example, the movement mechanism 114 may be attached to a wafer chuck or MEMS wafer holder. The movement mechanism 114 may provide scanning or movement in two axes (e.g., an x-axis and a y-axis). The movement mechanism 114 may change a position of the nozzle 112 relative to the target surface 102 according to a two-dimensional pattern (e.g., an X/Y scanning pattern). For example, the movement mechanism 114 may move the nozzle 112 or the object 104 such that the nozzle 112 moves over the target surface 102 to clean the target surface 102. In some implementations, the movement mechanism 114 may be used to mount the nozzle 112 perpendicularly to the target surface 102 such that desired gas discharge angles are achieved. In addition, the movement mechanism 114 may be configured to move the nozzle 112 relative to the target surface 102 on a third axis (e.g., a z-axis) in order to adjust a distance or gap between a tip of the nozzle 112 and the target surface 102.

The control system 116 may control the one or more respective gas pressures of the gas in each gas channel of the one or more gas channels, the vacuum pressure of the vacuum within the vacuum channel, and a movement of the nozzle or the object via the movement mechanism. Thus, the control system 116 may control a flow rate of the gas in each gas channel, and thus control the force of the gas applied to the target surface 102. Moreover, the control system 116 may control the suction force applied by the vacuum. Additionally, the control system 116 may control the two-dimensional pattern (e.g., a cleaning pattern). The control system 116 may control and synchronize individual subsystems of the surface cleaning system 100 and provide an interface to allow individual parameter adjustments to achieve optimized cleaning performance.

As indicated above, FIG. 1 is provided as an example. Other examples may differ from what is described with regard to FIG. 1.

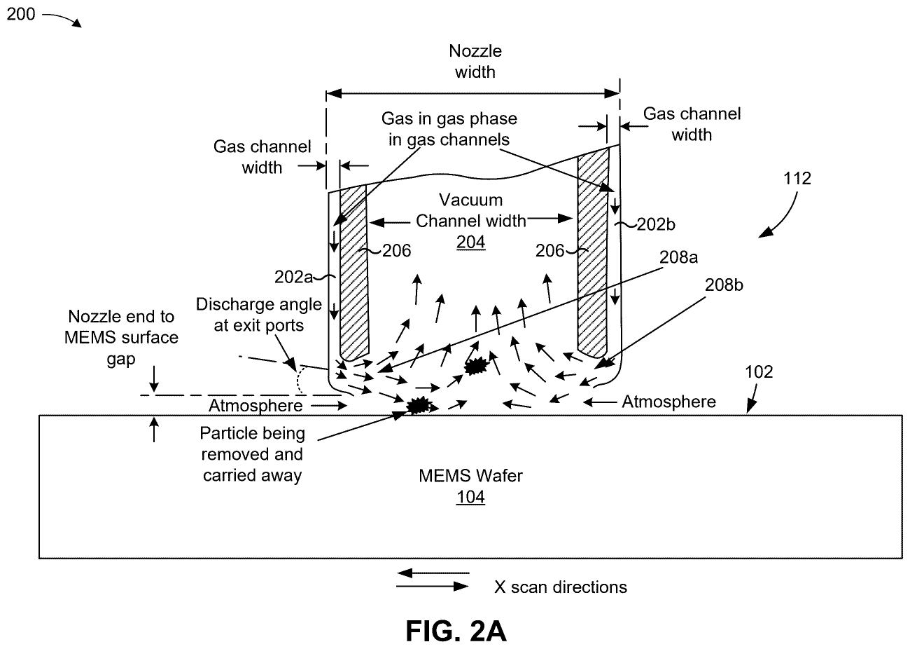

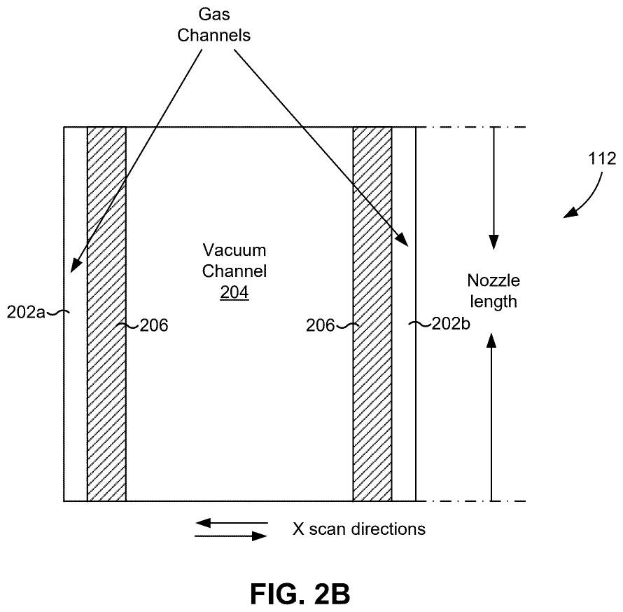

FIGS. 2A and 2B show a portion 200 of a surface cleaning system according to one or more implementations. The surface cleaning system may be associated with the surface cleaning system 100 described in connection with FIG. 1. In particular, the portion 200 shows a detailed cross-section of the nozzle 112 used for cleaning the target surface 102 of the object 104.

The nozzle 112 may include one or more gas channels 202a and 202b that are designed and/or configured to direct a gas, such as CO₂ gas, toward the target surface 102 at a low angle

relative to the target surface 102 in order to dislodge particles from the target surface 102. A single gas source may feed the one or more gas channels 202a and 202b. Alternatively, a separate gas source may be used to feed each respective gas channel for independent regulation of a gas flow rate in the respective gas channel.

Additionally, the nozzle 112 may include a vacuum channel 204 configured to apply a vacuum to the target surface 102 for vacuuming the particles away from the target surface 102. The nozzle 112 may include one or more spacers 206 that separate the one or more gas channels 202a and 202b from the vacuum channel 204. The one or more spacers 206 may form a hollow structure, such as a hollow cylinder, with a hollow center forming the vacuum channel 204. The one or more gas channels 202a and 202b may surround the one or more spacers 206. Thus, the vacuum channel 204 may be a center channel that extends along a center axis of the nozzle 112, and the one or more gas channels 202a and 202b may be arranged at a periphery of the nozzle 112, peripheral to the vacuum channel 204. Accordingly, the one or more spacers 206 may form internal walls that separate the one or more gas channels 202a and 202b from the vacuum channel 204.

Gas channel widths of the one or more gas channels 202a and 202b may be configured to increase a speed or flow rate of the gas injected into the one or more gas channels 202a and 202b by one or more gas sources. The one or more gas channels 202a and 202b may include one or more exit ports 208 from which the gas exits the nozzle 112. For example, gas channel 202a may include a first exit port 208a, and gas channel 202b may include a second exit port 208b. In some implementations, the gas channels 202a and 202b are conjoined or otherwise combined to form a single gas channel. The single gas channel may include one or more exit ports 208. For example, the single gas channel may include two exit ports (e.g., a first exit port and a second exit port), as shown in FIG. 2A.

The gas may be in a gas phase as the gas flows through the one or more gas channels 202a and 202b. Each gas channel of the one or more gas channels 202a and 202b may be designed and/or configured to cause adiabatic cooling of the gas at an exit of the nozzle 112 (e.g., at the exit ports 208) to form gas ice crystals. The one or more gas channels 202a and 202b may be designed and/or configured to direct a mixture of gas and gas ice crystals toward the target surface 102 at the low angle in order to dislodge the particles from the target surface 102.

In some implementations, the one or more gas channels 202a and 202b be a single gas channel having the first exit port 208a and/or the second exit port 208b configured to direct the gas toward the target surface 102 at the low angle. Thus, the single gas channel may have a single exit port or two exit ports. In some implementations, the single gas channel may have more than two exit ports. The first exit port 208a and/or the second exit port 208b may each have a parabolic shape that redirects the gas toward the target surface 102 and aligns a gas stream of the gas with the low angle (e.g., a discharge angle). The first exit port 208a and/or the second exit port 208b may be configured to form a high-speed flow of a gas and gas crystal mixture to generate a particle lifting force away from the target surface 102. For example, the first exit port 208a and/or the second exit port 208b may be configured to form a high-speed flow of a gas and gas crystal mixture to generate a particle lifting force away from the target surface 102 based on a Venturi effect.

In some implementations, the single gas channel may have two exit ports (e.g., the first exit port 208a and the second exit port 208b). The second exit port 208b may be arranged on a side of the vacuum channel 204 that is opposite to the first exit port 208a such that the second exit port 208b faces the first exit port 208a. Thus, the first exit port 208a and the second exit port 208b may form high-speed gas streams at low discharge angles that, together, create the particle lifting force. The high-speed gas streams may be a gas and gas crystal mixture, as described above.

In some implementations, the first exit port 208a may have a first parabolic shape that is configured to redirect the gas toward the target surface 102 in a first gas stream aligned with the low angle. Additionally, the second exit port 208b may have a second parabolic shape that is configured to redirect the gas toward the target surface 102 in a second gas stream aligned with the low angle.

In some implementations, the first exit port 208a and the second exit port 208b may be configured to form high speed flows of a gas and gas crystal mixture directed toward each other so that forces acting on a surface structure of the target surface 102 are balanced in order to protect the surface structure. The control system 116, described in connection with FIG. 1, may control the flow rates of the high speed flows to balance the forces acting on the target surface 102. When the forces are balanced or substantially balanced, the high speed flows may be less likely to damage the MEMS surface structures located at the target surface 102.

In some implementations, the one or more gas channels 202a and 202b may include a first gas channel 202a having the first exit port 208a configured to direct the gas toward the target surface 102 at a first low angle, and a second gas channel 202b having the second exit port 208b configured to direct the gas toward the target surface 102 at a second low angle. Thus, the first gas channel 202a and the second gas channel 202b may be separate gas channels. The first gas channel 202a and the second gas channel 202b may be arranged across the vacuum channel 204 from each other, on opposite sides of the nozzle 112. Thus, the second exit port 208b may be arranged on a side of the vacuum channel that is opposite to the first exit port 208a such that the second exit port 208b faces the first exit port 208a.

When pressurized gas exits from the first exit port 208a and the second exit port 208b with a parabolic shape, the gas may start to expand rapidly and increase speed. At the same time, adiabatic cooling may occur and gas crystals (e.g., CO₂ crystals) may form under the control of the gas and vacuum pressures. The temperature drop on the target surface 102 may weaken a bond between particles and the target surface 102. The gas and crystal mixture may be emitted at a low angle relative to the target surface 102, where the low angle at which the gas and gas crystal mixture is emitted may reduce downward pressure that may otherwise cause damage to movable surface structures located at the target surface 102. In some implementations, the gas flow angle may be defined by an exit port angle, which may have a value in a range from 1 to 30 degrees. The gas and gas crystal mixture may generally carry sufficient kinetic energy to dislodge particles from the target surface 102, and Venturi forces and vacuum pressure may carry the particles away to reduce a risk that the particles will land on any other location(s) of the object 104.

Furthermore, the design with dual exit ports may provide two opportunities for the gas and gas crystal mixture to contact the particles from two directions in each scanning path, because the dual exit ports face each other. In this way, an efficiency of particle cleaning may increase, and the cleaning efficiency of two opposite scan directions may be substantially the same.

In some implementations, the overall nozzle width may be based on a size of the surface movable structures of the MEMS devices, which may be in a range from a few millimeters (mm) up to 30 mm. The length of the nozzle may also be based on a size of the surface movable structures to be cleaned. Accordingly, as described herein, a CO₂ cleaning method may combine pressurized gas flow and a vacuum to create a gas and crystal mixture with a kinetic energy that is high enough to dislodge particles with minimum pressure applied on the movable surface structures. Furthermore, although certain nozzle design configurations are described herein, other nozzle configurations may be used, such as a single exit port structure or dual exit ports that face away from each other.

In some implementations, to achieve an optimized cleaning power and efficiency, the surface cleaning system described herein may support different process configurations for performing the surface cleaning. For example, in some implementations, parameters for the process configuration that can be adjusted and optimized may include a pressure of the gas, a vacuum pressure, a gap between a nozzle end surface (e.g., tip) and the target surface 102 (e.g., a chuck height), an orientation of a scanning direction relative to the surface movable structures (e.g., a chuck rotation angle), a scanning speed across the target surface 102 in a first axis, such as an x-axis (e.g., a chuck speed in a direction of the first axis), and/or a scanning step size in a second axis, such as a y-axis (e.g., a chuck step size in a direction of the second axis). A shape of the nozzle 112 may be rectangular, cylindrical, or another shape suitable for housing one or more gas channels 202a and 202b and the vacuum channel 204.

As indicated above, FIGS. 2A and 2B are provided as examples. Other examples may differ from what is described with regard to FIGS. 2A and 2B.

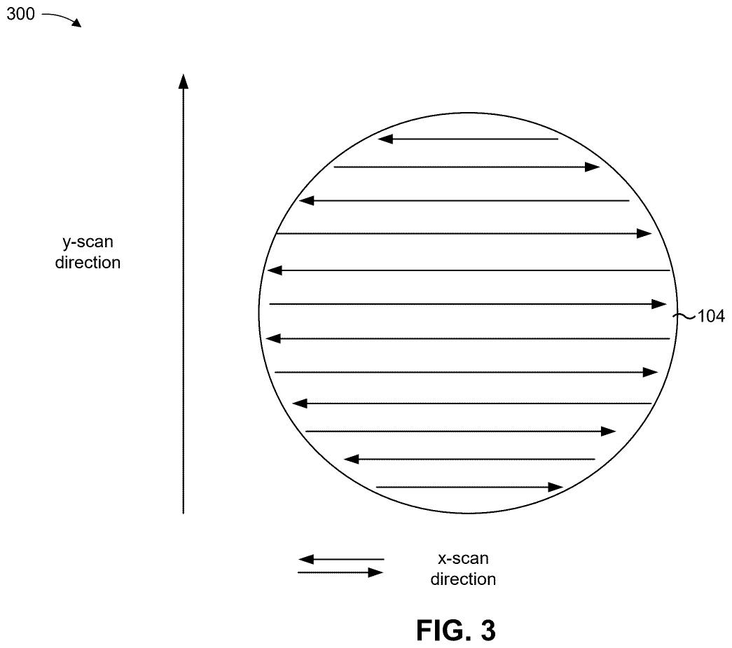

FIG. 3 shows an example 300 of a scanning pattern of a nozzle relative to a target surface. For example, FIG. 3 shows a plan view of the object 104. The nozzle may move across the object 104 in two scan directions (e.g., an x-scan direction and a y-scan direction). Thus, the nozzle may move across the object 104 according to a two-dimensional pattern (e.g., an X/Y scanning pattern). The discharge angle of the exit ports may be directed along the x-scan direction (e.g., with the x-axis) such that the gas streams are forced to flow along the x-axis.

As indicated above, FIG. 3 is provided as an example. Other examples may differ from what is described with regard to FIG. 3.

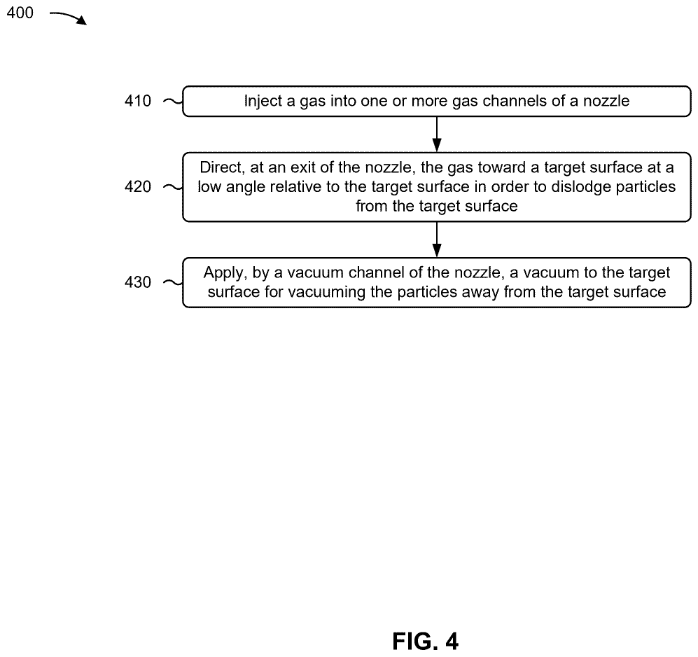

FIG. 4 is a flowchart of an example process 400 associated with a micro-particle cleaning method for MEMS devices with movable surface structures. One or more process blocks of FIG. 4 are performed by a surface cleaning system (e.g., surface cleaning system 100). Additionally, or alternatively, one or more process blocks of FIG. 4 may be performed by one or more components of the surface cleaning system 100, such as one or more gas sources 106 and 108, vacuum source 110, nozzle 112, movement mechanism 114, and/or control system 116.

As shown in FIG. 4, process 400 includes injecting a gas into one or more gas channels of a nozzle (block 410). For example, one or more gas sources 106 and 108 may inject a gas into one or more gas channels of nozzle 112, as described above.

As further shown in FIG. 4, process 400 includes directing, at an exit of the nozzle, the gas toward a target surface at a low angle relative to the target surface in order to dislodge particles from the target surface (block 420). For example, nozzle 112 may direct, at an exit of the nozzle 112, the gas toward a target surface 102 at a low angle relative to the target surface 102 in order to dislodge particles from the target surface 102, as described above.

As further shown in FIG. 4, process 400 includes applying a vacuum to the target surface for vacuuming the particles away from the target surface (block 430). For example, the vacuum source 110 may apply a vacuum, via a vacuum channel of the nozzle 112, to the target surface 102 for vacuuming the particles away from the target surface 102, as described above.

Process 400 may include additional aspects, such as any single aspect or any combination of aspects described below and/or in connection with one or more other processes described elsewhere herein.

In a first aspect, process 400 includes regulating a gas pressure of the gas in the one or more gas channels, and regulating a vacuum pressure of the vacuum applied by the vacuum channel. For example, the control system 116 may regulate a gas pressure of the gas in the one or more gas channels, and regulate a vacuum pressure of the vacuum applied by the vacuum channel, as described above.

In a second aspect, the gas pressure and the vacuum pressure are regulated such that the gas exiting the nozzle undergoes adiabatic cooling to form gas ice crystals that are directed toward the target surface by the nozzle.

In a third aspect, the target surface is a surface of a MEMS wafer.

Although FIG. 4 shows example blocks of process 400, in some implementations, process 400 includes additional blocks, fewer blocks, different blocks, or differently arranged blocks than those depicted in FIG. 4. Additionally, or alternatively, two or more of the blocks of process 400 may be performed in parallel.

The following provides an overview of some Aspects of the present disclosure:
Aspect 1: A surface cleaning system, comprising: one or more gas sources configured to provide a gas at one or more respective gas pressures; a vacuum source configured to provide a vacuum at a vacuum pressure; a nozzle comprising: one or more gas channels fluidly coupled to the one or more gas sources, the one or more gas channels configured to direct the gas toward a target surface at a low angle relative to the target surface in order to dislodge particles from the target surface; and a vacuum channel fluidly coupled to the vacuum source, the vacuum channel configured to apply the vacuum to the target surface for vacuuming the particles away from the target surface; a movement mechanism attached to the nozzle or to an object of the target surface, wherein the movement mechanism is configured to change a position of the nozzle relative to the target surface according to a two-dimensional pattern; and a control system configured to control the one or more respective gas pressures of the gas in each gas channel of the one or more gas channels, the vacuum pressure of the vacuum within the vacuum channel, and a movement of the nozzle or the object via the movement mechanism.
Aspect 2: The surface cleaning system of Aspect 1, wherein the nozzle includes a nozzle tip that is arranged facing the target surface, wherein the nozzle tip is arranged substantially perpendicular to the target surface, and wherein the nozzle tip includes one or more exit ports fluidly coupled to the one or more gas channels for directing the gas toward the target surface, and a vacuum inlet of the vacuum channel at which the particles and discharged gas enter the vacuum channel.
Aspect 3: The surface cleaning system of any of Aspects 1-2, wherein the low angle is in a range of 1-30°.
Aspect 4: The surface cleaning system of any of Aspects 1-3, wherein the gas is configured to form a mixture of gas and gas ice crystals via adiabatic cooling to dislodge the particles from the target surface.
Aspect 5: The surface cleaning system of any of Aspects 1-4, wherein the gas induces a temperature drop at the target surface to weaken a bond between particles and the target surface.
Aspect 6: The surface cleaning system of any of Aspects 1-5, wherein the gas is a carbon dioxide (CO₂) gas.
Aspect 7: The surface cleaning system of any of Aspects 1-6, wherein the target surface is a surface of a micro-electromechanical systems (MEMS) wafer.
Aspect 8: The surface cleaning system of Aspect 7, wherein the MEMS wafer includes a plurality of MEMS mirror structures arranged at the target surface.
Aspect 9: A nozzle of a surface cleaning system, the nozzle comprising: one or more gas channels configured to direct a gas toward a target surface at a low angle relative to the target surface in order to dislodge particles from the target surface; and a vacuum channel configured to apply a vacuum to the target surface for vacuuming the particles away from the target surface.
Aspect 10: The nozzle of Aspect 9, wherein each gas channel of the one or more gas channels is configured to cause adiabatic cooling of the gas at an exit of the nozzle to form gas ice crystals, and wherein the one or more gas channels are configured to direct a mixture of gas and gas ice crystals toward the target surface at the low angle in order to dislodge the particles from the target surface.
Aspect 11: The nozzle of any of Aspects 9-10, wherein the vacuum channel is a center channel that extends along a center axis of the nozzle, and wherein the one or more gas channels are arranged at a periphery of the nozzle, peripheral to the vacuum channel.
Aspect 12: The nozzle of Aspect 11, wherein the one or more gas channels is a single gas channel having a first exit port configured to direct the gas toward the target surface at the low angle.
Aspect 13: The nozzle of Aspect 12, wherein the first exit port has a parabolic shape that redirects the gas toward the target surface and aligns a gas stream of the gas with the low angle.
Aspect 14: The nozzle of Aspect 12, wherein the first exit port is configured to form a high-speed flow of gas and gas crystal mixture to generate a particle lifting force away from the target surface.
Aspect 15: The nozzle of Aspect 12, wherein the single gas channel has a second exit port configured to direct the gas toward the target surface at the low angle, and wherein the second exit port is arranged on a side of the vacuum channel that is opposite to the first exit port such that the second exit port faces the first exit port.
Aspect 16: The nozzle of Aspect 15, wherein the first exit port has a first parabolic shape that is configured to redirect the gas toward the target surface in a first gas stream aligned with the low angle, and wherein the second exit port has a second parabolic shape that is configured to redirect the gas toward the target surface in a second gas stream aligned with the low angle.
Aspect 17: The nozzle of Aspect 15, wherein the first exit port and the second exit port are configured to form high speed flows of gas and gas crystal mixture directed toward each other so that forces acting on a surface structure of the target surface are balanced in order to protect the surface structure.
Aspect 18: The nozzle of Aspect 12, wherein the single gas channel surrounds the vacuum channel.
Aspect 19: The nozzle of Aspect 11, wherein the one or more gas channels include: a first gas channel having a first exit port configured to direct the gas toward the target surface at a first low angle; and a second gas channel having a second exit port configured to direct the gas toward the target surface at a second low angle.
Aspect 20: The nozzle of Aspect 19, wherein the second exit port is arranged on a side of the vacuum channel that is opposite to the first exit port such that the second exit port faces the first exit port.
Aspect 21: A method for cleaning a surface, the method comprising: injecting a gas into one or more gas channels of a nozzle; directing, at an exit of the nozzle, the gas toward a target surface at a low angle relative to the target surface in order to dislodge particles from the target surface; and applying, by a vacuum channel of the nozzle, a vacuum to the target surface for vacuuming the particles away from the target surface.
Aspect 22: The method of Aspect 21, further comprising: regulating a gas pressure of the gas in the one or more gas channels; and regulating a vacuum pressure of the vacuum applied by the vacuum channel.
Aspect 23: The method of Aspect 22, wherein the gas pressure and the vacuum pressure are regulated such that the gas exiting the nozzle undergoes adiabatic cooling to form gas ice crystals that are directed toward the target surface by the nozzle.
Aspect 24: The method of any of Aspects 21-23, wherein the target surface is a surface of a micro-electromechanical systems (MEMS) wafer.
Aspect 25: A system configured to perform one or more operations recited in one or more of Aspects 1-24.
Aspect 26: An apparatus comprising means for performing one or more operations recited in one or more of Aspects 1-24.

The foregoing disclosure provides illustration and description, but is not intended to be exhaustive or to limit the implementations to the precise forms disclosed. Modifications and variations may be made in light of the above disclosure or may be acquired from practice of the implementations. Furthermore, any of the implementations described herein may be combined unless the foregoing disclosure expressly provides a reason that one or more implementations may not be combined.

Even though particular combinations of features are recited in the claims and/or disclosed in the specification, these combinations are not intended to limit the disclosure of various implementations. In fact, many of these features may be combined in ways not specifically recited in the claims and/or disclosed in the specification. Although each dependent claim listed below may directly depend on only one claim, the disclosure of various implementations includes each dependent claim in combination with every other claim in the claim set. As used herein, a phrase referring to “at least one of” a list of items refers to any combination of those items, including single members. As an example, “at least one of: a, b, or c” is intended to cover a, b, c, a-b, a-c, b-c, and a-b-c, as well as any combination with multiple of the same item.

When a component or one or more components (e.g., a laser emitter or one or more laser emitters) is described or claimed (within a single claim or across multiple claims) as performing multiple operations or being configured to perform multiple operations, this language is intended to broadly cover a variety of architectures and environments. For example, unless explicitly claimed otherwise (e.g., via the use of “first component” and “second component” or other language that differentiates components in the claims), this language is intended to cover a single component performing or being configured to perform all of the operations, a group of components collectively performing or being configured to perform all of the operations, a first component performing or being configured to perform a first operation and a second component performing or being configured to perform a second operation, or any combination of components performing or being configured to perform the operations. For example, when a claim has the form “one or more components configured to: perform X; perform Y; and perform Z,” that claim should be interpreted to mean “one or more components configured to perform X; one or more (possibly different) components configured to perform Y; and one or more (also possibly different) components configured to perform Z.”

No element, act, or instruction used herein should be construed as critical or essential unless explicitly described as such. Also, as used herein, the articles “a” and “an” are intended to include one or more items, and may be used interchangeably with “one or more.” Further, as used herein, the article “the” is intended to include one or more items referenced in connection with the article “the” and may be used interchangeably with “the one or more.” Furthermore, as used herein, the term “set” is intended to include one or more items (e.g., related items, unrelated items, or a combination of related and unrelated items), and may be used interchangeably with “one or more.” Where only one item is intended, the phrase “only one” or similar language is used. Also, as used herein, the terms “has,” “have,” “having,” or the like are intended to be open-ended terms. Further, the phrase “based on” is intended to mean “based, at least in part, on” unless explicitly stated otherwise. Also, as used herein, the term “or” is intended to be inclusive when used in a series and may be used interchangeably with “and/or,” unless explicitly stated otherwise (e.g., if used in combination with “either” or “only one of”). Further, spatially relative terms, such as “below,” “lower,” “above,” “upper,” and the like, may be used herein for ease of description to describe one element or feature's relationship to another element(s) or feature(s) as illustrated in the figures. The spatially relative terms are intended to encompass different orientations of the apparatus, device, and/or element in use or operation in addition to the orientation depicted in the figures. The apparatus may be otherwise oriented (rotated 90 degrees or at other orientations) and the spatially relative descriptors used herein may likewise be interpreted accordingly.

What is claimed is:

1. A surface cleaning system, comprising:
one or more gas sources configured to provide a gas at one or more respective gas pressures;
a vacuum source configured to provide a vacuum at a vacuum pressure;
a nozzle comprising:
one or more gas channels fluidly coupled to the one or more gas sources, the one or more gas channels configured to direct the gas toward a target surface at a low angle relative to the target surface in order to dislodge particles from the target surface; and
a vacuum channel fluidly coupled to the vacuum source, the vacuum channel configured to apply the vacuum to the target surface for vacuuming the particles away from the target surface;
a movement mechanism attached to the nozzle or to an object of the target surface, wherein the movement mechanism is configured to change a position of the nozzle relative to the target surface according to a two-dimensional pattern; and
a control system configured to control the one or more respective gas pressures of the gas in each gas channel of the one or more gas channels, the vacuum pressure of the vacuum within the vacuum channel, and a movement of the nozzle or the object via the movement mechanism.

2. The surface cleaning system of claim 1, wherein the nozzle includes a nozzle tip that is arranged facing the target surface,
wherein the nozzle tip is arranged substantially perpendicular to the target surface, and
wherein the nozzle tip includes one or more exit ports fluidly coupled to the one or more gas channels for directing the gas toward the target surface, and a vacuum inlet of the vacuum channel at which the particles and discharged gas enter the vacuum channel.

3. The surface cleaning system of claim 1, wherein the low angle is in a range of 1-30°.

4. The surface cleaning system of claim 1, wherein the gas is configured to form a mixture of gas and gas ice crystals via adiabatic cooling to dislodge the particles from the target surface.

5. The surface cleaning system of claim 1, wherein the gas induces a temperature drop at the target surface to weaken a bond between particles and the target surface.

6. The surface cleaning system of claim 1, wherein the gas is a carbon dioxide (CO₂) gas.

7. The surface cleaning system of claim 1, wherein the target surface is a surface of a micro-electromechanical systems (MEMS) wafer.

8. The surface cleaning system of claim 7, wherein the MEMS wafer includes a plurality of MEMS mirror structures arranged at the target surface.

9. A nozzle of a surface cleaning system, the nozzle comprising:
one or more gas channels configured to direct a gas toward a target surface at a low angle relative to the target surface in order to dislodge particles from the target surface; and
a vacuum channel configured to apply a vacuum to the target surface for vacuuming the particles away from the target surface.

10. The nozzle of claim 9, wherein each gas channel of the one or more gas channels is configured to cause adiabatic cooling of the gas at an exit of the nozzle to form gas ice crystals, and
wherein the one or more gas channels are configured to direct a mixture of gas and gas ice crystals toward the target surface at the low angle in order to dislodge the particles from the target surface.

11. The nozzle of claim 9, wherein the vacuum channel is a center channel that extends along a center axis of the nozzle, and
wherein the one or more gas channels are arranged at a periphery of the nozzle, peripheral to the vacuum channel.

12. The nozzle of claim 11, wherein the one or more gas channels is a single gas channel having a first exit port configured to direct the gas toward the target surface at the low angle.

13. The nozzle of claim 12, wherein the first exit port has a parabolic shape that redirects the gas toward the target surface and aligns a gas stream of the gas with the low angle.

14. The nozzle of claim 12, wherein the first exit port is configured to form a high-speed flow of a gas and gas crystal mixture to generate a particle lifting force away from the target surface.

15. The nozzle of claim 12, wherein the single gas channel has a second exit port configured to direct the gas toward the target surface at the low angle, and
wherein the second exit port is arranged on a side of the vacuum channel that is opposite to the first exit port such that the second exit port faces the first exit port.

16. The nozzle of claim 15, wherein the first exit port has a first parabolic shape that is configured to redirect the gas toward the target surface in a first gas stream aligned with the low angle, and
wherein the second exit port has a second parabolic shape that is configured to redirect the gas toward the target surface in a second gas stream aligned with the low angle.

17. The nozzle of claim 15, wherein the first exit port and the second exit port are configured to form high speed flows of a gas and gas crystal mixture directed toward each other so that forces acting on a surface structure of the target surface are balanced in order to protect the surface structure.

18. The nozzle of claim 12, wherein the single gas channel surrounds the vacuum channel.

19. The nozzle of claim 11, wherein the one or more gas channels include:
a first gas channel having a first exit port configured to direct the gas toward the target surface at a first low angle; and
a second gas channel having a second exit port configured to direct the gas toward the target surface at a second low angle.

20. The nozzle of claim 19, wherein the second exit port is arranged on a side of the vacuum channel that is opposite to the first exit port such that the second exit port faces the first exit port.

21. A method for cleaning a surface, the method comprising:
injecting a gas into one or more gas channels of a nozzle;
directing, at an exit of the nozzle, the gas toward a target surface at a low angle relative to the target surface in order to dislodge particles from the target surface; and
applying, by a vacuum channel of the nozzle, a vacuum to the target surface for vacuuming the particles away from the target surface.
